(19) United States
(12) Patent Application Publication
(10) Pub. No.: US 2026/0363090 A1
(43) Pub. Date: Nov. 12, 2026

(54) WAVEGUIDE ON SUPPORT STRUCTURES

(71) Applicant: GlobalFoundries U.S. Inc., Malta, NY (US)

(72) Inventors: WILLIAM TAYLOR, Clifton Park, NY (US); NIGEL CAVE, Saratoga Springs, NY (US)

(21) Appl. No.: 19/200,746

(22) Filed: May 7, 2025

(51) Int. Cl. H10W 44/20

(52) U.S. Cl. CPC H10W 44/20; H10W 44/216

(57) ABSTRACT

The disclosed subject matter relates to semiconductor devices for use in optoelectronic/photonic applications and optical sensors. More particularly, the present disclosure relates to a structure in a semiconductor device having a waveguide with supported segments on support structures and a suspended segment with surfaces capable of being directly exposed to gas, vacuum, or liquid. The present disclosure also relates to an integrated circuit (IC) chip including the structure.

### FIELD OF THE INVENTION

The present disclosure generally relates to semiconductor devices for use in optoelectronic/photonic applications, and optical sensors. More particularly, the present disclosure relates to a structure in a semiconductor device having a waveguide with segments on support structures. The present disclosure also relates to an integrated circuit (IC) chip including the structure.

### BACKGROUND

Silicon photonics is a platform for potentially revolutionary advances in the fields of telecommunications, data communications, medical technology, security, quantum computing, and sensing. Silicon photonics has the potential to realize small, highly integrated, photonics sub-systems that leverage off the decades of silicon fabrication experience, technology, and scalability to gain access to the full potential of the silicon platform, i.e. silicon photonics for high-speed signaling and sensing, and complementary metal-oxide semiconductor (CMOS) electronics for subsequent logical operations and computations. Such multi-chip integration also allows for the bridging of different functional technologies, such as micro-electro-mechanical systems (MEMS), III-V materials, non-CMOS application-specific integrated circuits (ASIC), etc.

Optoelectronic or photonic devices are types of semiconductor devices that include components capable of at least detecting, transmitting, manipulating, and harnessing electromagnetic energy, such as light. An example of components in the optoelectronic devices is optical sensors, such as interferometers. Optical sensors that are operating at smaller wavelengths are found to be difficult to fabricate since the material directly surrounding the optical sensors also inadvertently absorbs electromagnetic waves at those operating wavelengths, which may adversely impact the sensitivity and increase the signal loss of the optical sensors.

### SUMMARY

In an aspect of the present disclosure, there is provided a structure in a semiconductor device including a first support structure over a substrate, a second support structure over the substrate, a waveguide structure having a first segment directly on the first support structure, a second segment directly on the second support structure, and a suspended segment between and adjoining the first segment and the second segment, and a cavity above the substrate and laterally between the first support structure and the second support structure, in which the suspended segment has a lower surface directly exposed to the cavity. The waveguide structure is configured to guide electromagnetic waves to traverse between the first segment and the second segment.

In another aspect of the present disclosure, there is provided a structure in a semiconductor device including a first support structure over a substrate, a second support structure over the substrate, a waveguide structure having a plurality of structure sections, each structure section includes a first supported segment directly on the first support structure, a second supported segment directly on the second support structure, and a suspended segment between and adjoining the first supported segment and the second supported segment, and a cavity above the substrate and laterally between the first support structure and the second support structure, in which the suspended segment in each structure section of the plurality of structure sections is suspended over the substrate, and the suspended segment in each structure section of the plurality of structure sections has a lower surface directly exposed to the cavity. The waveguide structure is configured to guide electromagnetic waves to traverse, in each structure section, between the first supported segment and the second supported segment.

In yet another aspect of the present disclosure, there is provided a structure in a semiconductor device including a first support structure over a substrate, a second support structure over the substrate, a waveguide structure having a first supported segment directly on the first support structure, a second supported segment directly on the second support structure, and a suspended segment between and adjoining the first supported segment and the second supported segment, and a cavity above the substrate and laterally between the first support structure and the second support structure, in which the suspended segment is suspended over the substrate, and the suspended segment of the waveguide structure has a lower surface directly exposed to the cavity. The suspended segment of the waveguide structure has a longitudinal length and a cross-sectional area, in which the cross-sectional area of the suspended segment of the waveguide structure is constant along the longitudinal length of the suspended segment of the waveguide structure.

### BRIEF DESCRIPTION OF THE DRAWINGS

The present disclosure may be understood by reference to the following description taken in conjunction with the accompanying drawings.

For simplicity and clarity of illustration, the drawings illustrate the general manner of construction, and certain descriptions and details of features and techniques may be omitted to avoid unnecessarily obscuring the discussion of the described embodiments of the present disclosure. Additionally, elements in the drawings are not necessarily drawn to scale. For example, the dimensions of some of the elements in the drawings may be exaggerated relative to other elements to help improve understanding of embodiments of the present disclosure. The same reference numerals in different drawings denote the same elements, while similar reference numerals may, but do not necessarily, denote similar elements or materials.

FIG. 1 is a top-down view depicting an example of a structure having a waveguide on support structures.

FIG. 2A is a cross-sectional view taken along section line AA in FIG. 1 depicting the example of the structure shown in FIG. 1.

FIG. 2B is a cross-sectional view taken along section line BB in FIG. 1 depicting the example of the structure shown in FIG. 1.

FIG. 2C is a cross-sectional view taken along section line CC in FIG. 1 depicting the example of the structure shown in FIG. 1.

FIG. 3 is a perspective view of the example of the structure shown in FIG. 1, and FIG. 2A to FIG. 2C.

FIG. 3A is a perspective view of an example modification of the structure shown in FIG. 3 where more than one waveguides on support structures are formed over a single substrate.

FIG. 4 is a top-down view depicting another example of a structure having a waveguide on support structures.

FIG. 5A is a cross-sectional view taken along section line AA in FIG. 4 depicting the example of the structure shown in FIG. 4.

FIG. 5B is a cross-sectional view taken along section line BB in FIG. 4 depicting the example of the structure shown in FIG. 4.

FIG. 5C is a cross-sectional view taken along section line CC in FIG. 4 depicting the example of the structure shown in FIG. 4.

FIG. 5D is a cross-sectional view taken along section line DD in FIG. 4 depicting the example of the structure shown in FIG. 4.

FIG. 5E is a cross-sectional view taken along section line EE in FIG. 4 depicting the example of the structure shown in FIG. 4.

FIG. 6 is a perspective view of the example of the structure shown in FIG. 4, and FIG. 5A to FIG. 5E.

FIG. 7, FIG. 9, and FIG. 11 are top-down views of structures at various stages of forming the exemplary structure shown in FIG. 1.

FIG. 8A and FIG. 8B, FIG. 10A and FIG. 10B, FIG. 12A to FIG. 12C, and FIG. 13A to

FIG. 13E are cross-sectional views of structures at various stages of forming the exemplary structure shown in FIG. 3A.

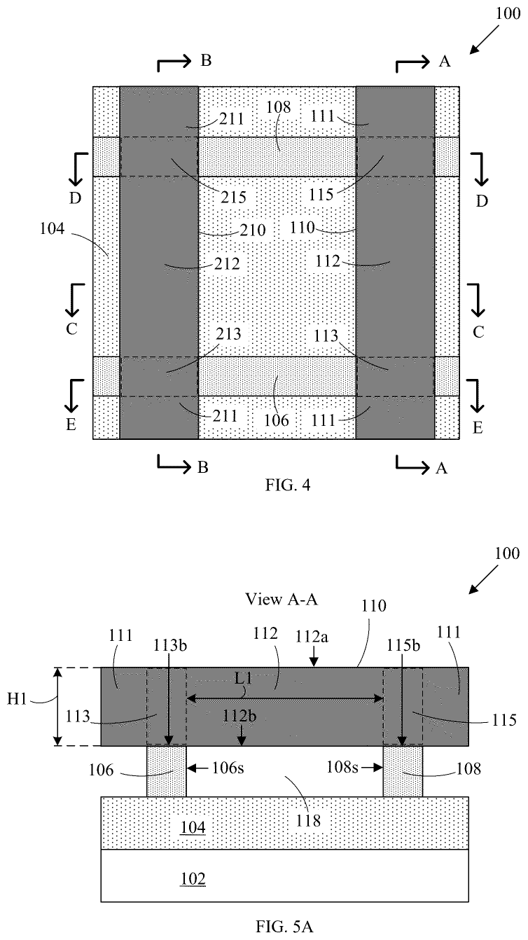

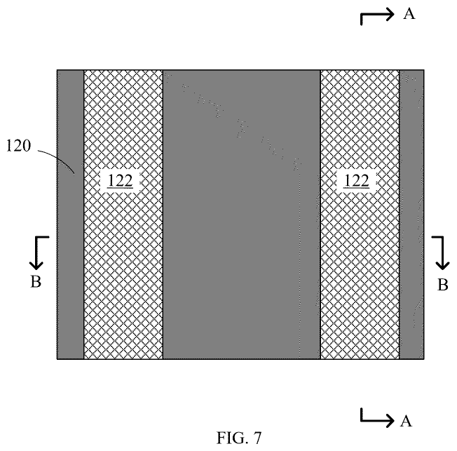

FIG. 7, FIG. 9, and FIG. 14 are top-down views of structures at various stages of forming the exemplary structure shown in FIG. 4.

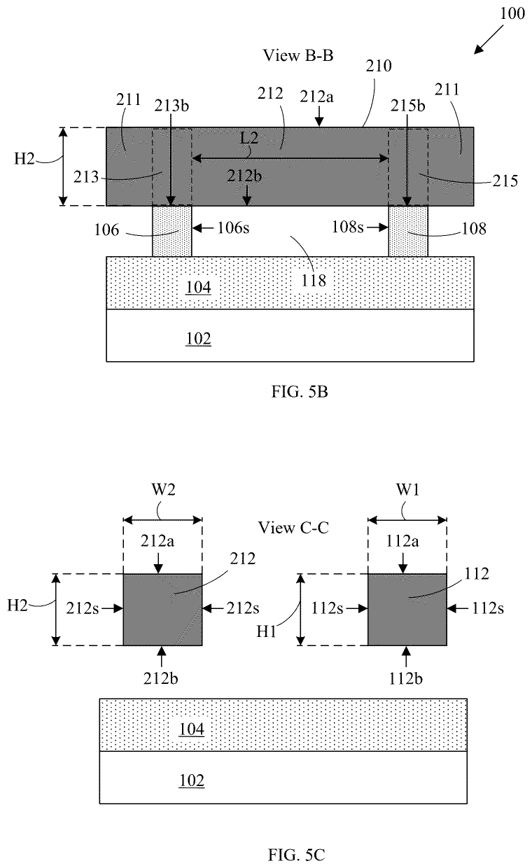

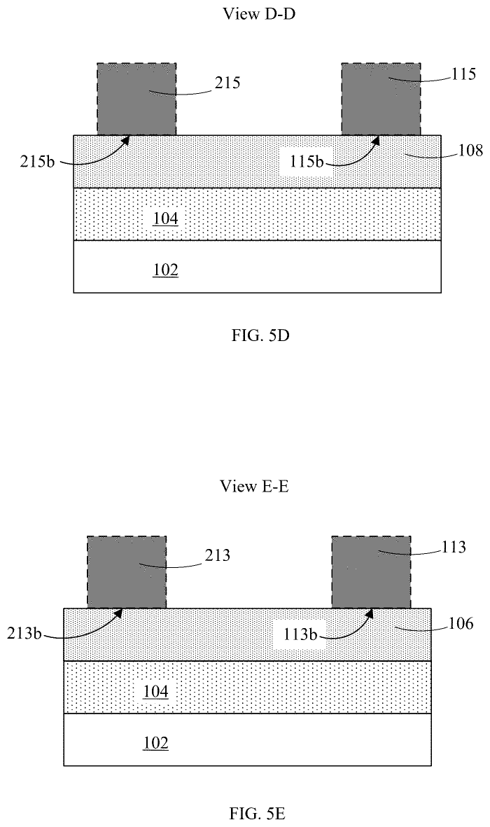

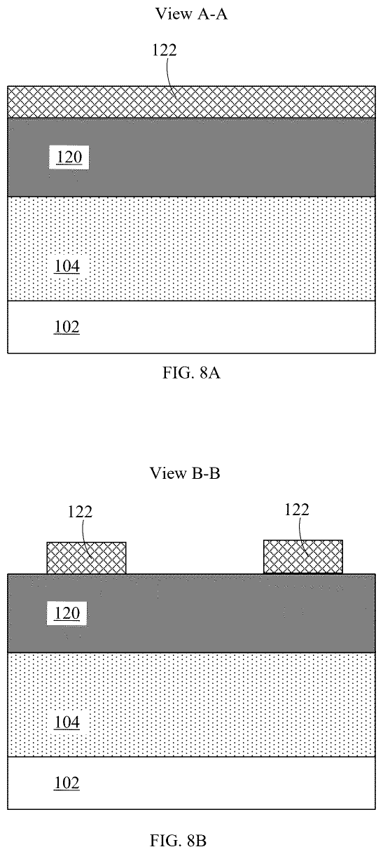

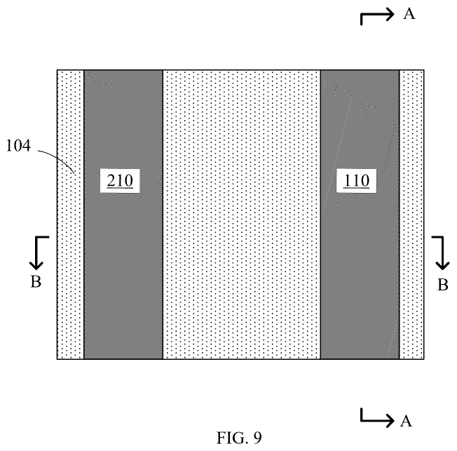

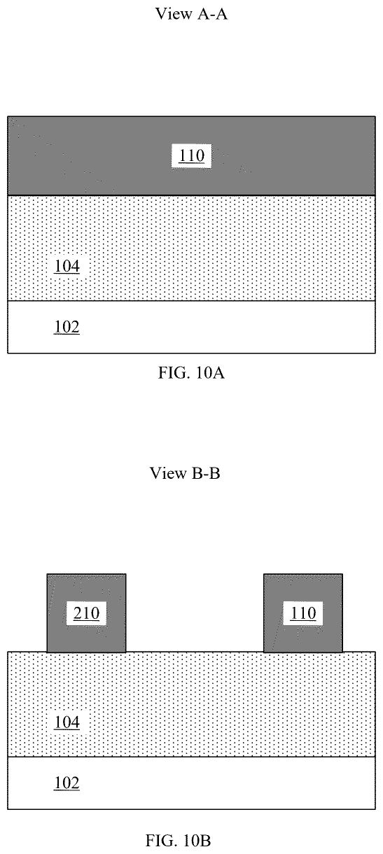

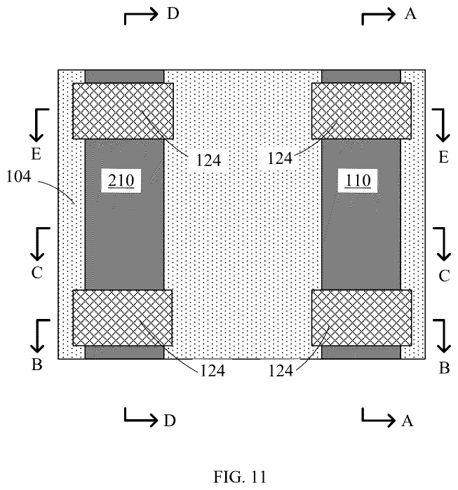

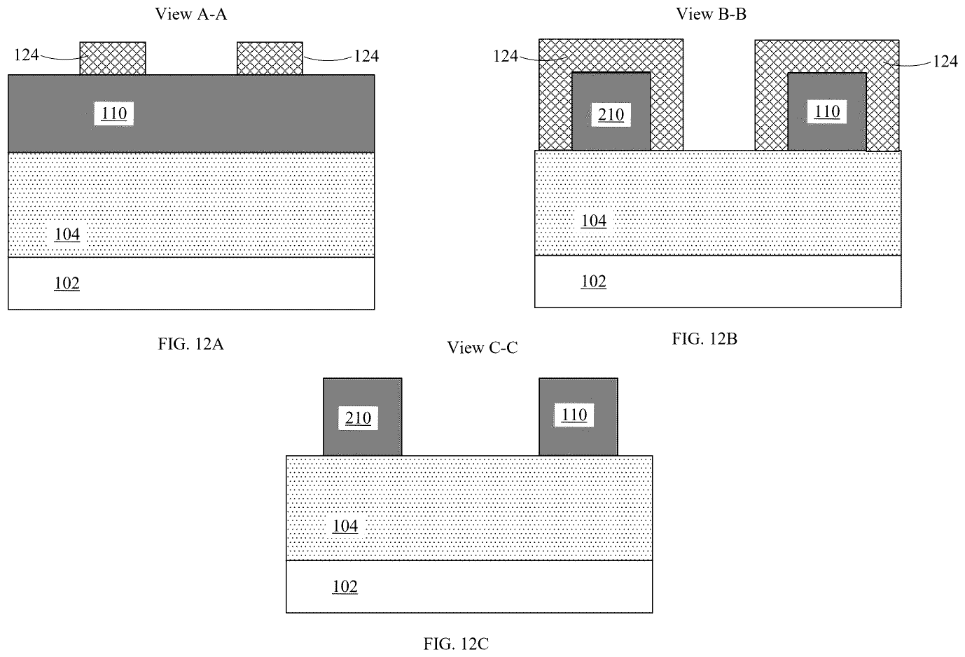

FIG. 8A and FIG. 8B, FIG. 10A and FIG. 10B, FIG. 15A to FIG. 15C, and FIG. 16A to FIG. 16E are cross-sectional views of structures at various stages of forming the exemplary structure shown in FIG. 5A to FIG. 5E.

FIG. 17 is a top-down view of an exemplary IC chip including the structures described in the present disclosure.

FIG. 18 is a top-down view of another exemplary IC chip including the structures described in the present disclosure.

### DETAILED DESCRIPTION

Various illustrative embodiments of the present disclosure are described below. The embodiments disclosed herein are exemplary and not intended to be exhaustive or limiting to the present disclosure.

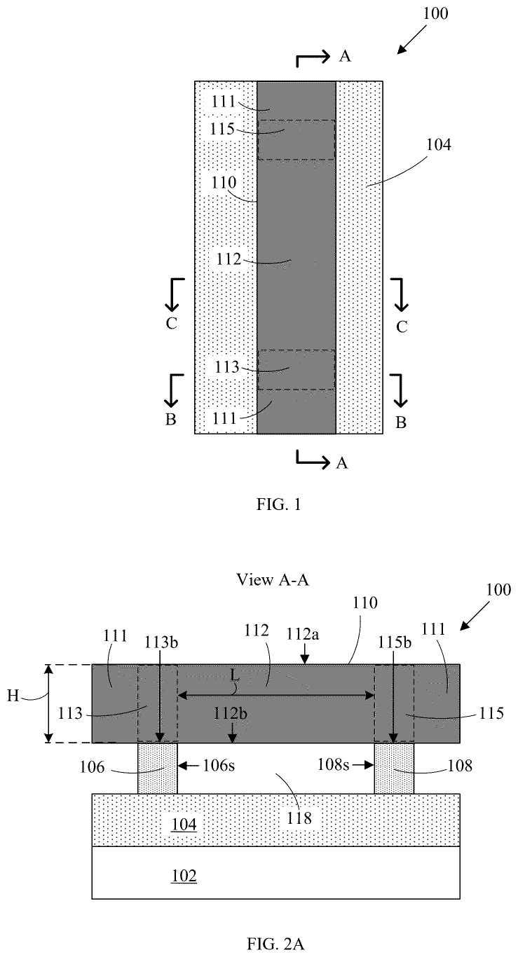

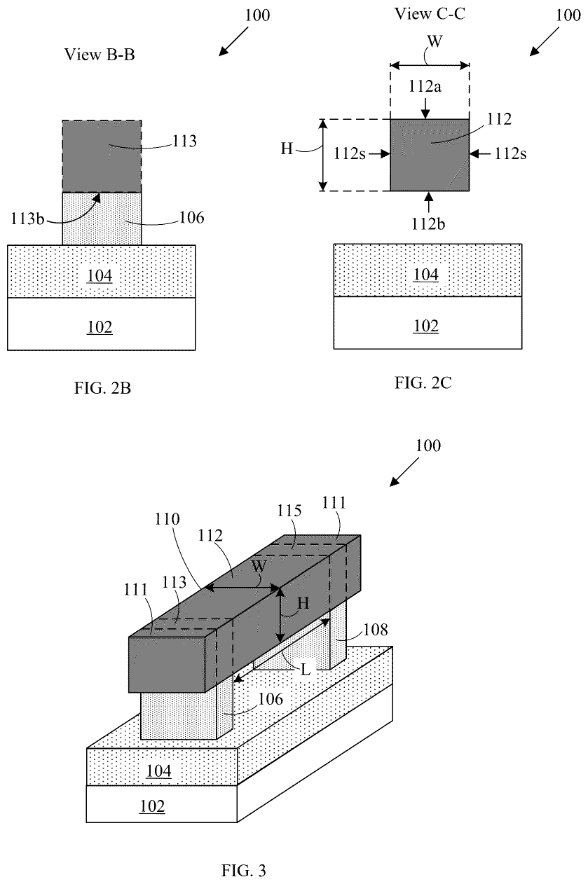

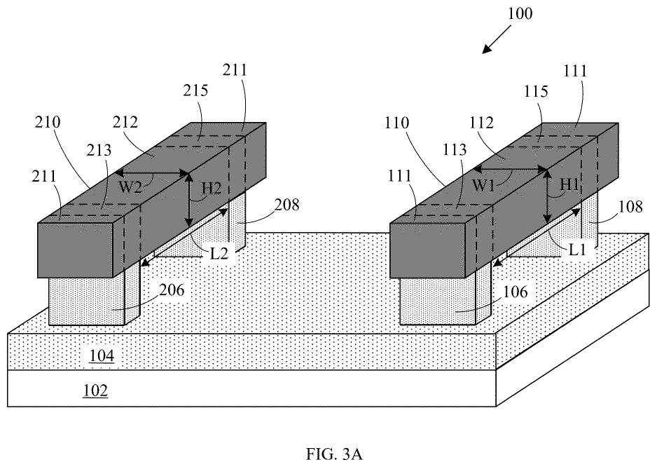

Referring to FIG. 1, FIG. 2A to FIG. 2C, and FIG. 3, a structure 100 in a semiconductor device for use in optoelectronic or photonic applications may include a waveguide structure 110, a first support structure 106, and a second support structure 108. The first support structure 106 and the second support structure 108 may be over a substrate 102. The waveguide structure 110 may include segments, for example, segments that may be supported and segments that may be suspended. The waveguide structure 110 may include a first segment 113, a second segment 115, and a suspended segment 112. The first segment 113 may be directly on the first support structure 106 and the second segment 115 may be directly on the second support structure 108. The suspended segment 112 may be between and adjoining the first segment 113 and the second segment 115. The suspended segment 112 may be suspended over the substrate 102. A cavity 118 may be above the substrate 102, below the waveguide structure 110, and laterally between the first support structure 106 and the second support structure 108. The cavity 118 may be either filled with gas or liquid, or in a state of vacuum. The cavity 118 may be an open cavity and not completely sealed. In some embodiments, the first segment 113 and the second segment 115 may be referred to as the first supported segment 113 and the second supported segment 115.

In various implementations, an insulator layer 104 may be positioned directly on the substrate 102. The support structures 106, 108 may be positioned directly on the insulator layer 104. The cavity 118 may be above the insulator layer 104, and the insulator layer 104 may be directly exposed to the cavity 118. The suspended segment 112 may be suspended over the portion of the insulator layer 104 laterally between the support structures 106, 108. In alternative implementations (not shown), the support structures 106, 108 may be positioned directly on the substrate 102, and the substrate 102 may be directly exposed to the cavity 118.

In an embodiment, the waveguide structure 110 shown in FIG. 1, FIG. 2A, and FIG. 3 may have overhang segments 111 extending from the supported segments 113, 115 to suspend above the substrate 102. Alternatively, as will be shown in other drawings of the present disclosure, instead of having overhang segments 111 extending from the supported segments 113, 115, the supported segments 113, 115 may adjoin suspended segments of other waveguide structure sections.

As shown in FIG. 2A and FIG. 2B, the first supported segment 113 may have a lower surface 113b and the second supported segment 115 may have a lower surface 115b. In various implementations, the respective lower surface 113b, 115b of the supported segments 113, 115 may be the lowermost surface. The lower surface 113b of the first supported segment 113 may be directly on the first support structure 106. The lower surface 115b of the second supported segment 115 may be directly on the second support structure 108. In an implementation, only the lower surface 113b of the first supported segment 113 may be in direct contact with the first support structure 106, and only the lower surface 115b of the second supported segment 115 may be in direct contact with the second support structure 108. The remaining surfaces of the first supported segment 113 and the remaining surfaces of the second supported segment 115 may not be in direct contact with any solid materials, such as dielectric materials, metals, or semiconductor materials.

As shown in FIG. 2A and FIG. 2C, the suspended segment 112 of the waveguide structure 110 may have a lower surface 112b, an upper surface 112a, and side surfaces 112s. The cavity 118 may be aligned vertically below the suspended segment 112 of the waveguide structure 110 such that the lower surface 112b of the suspended segment 112 of the waveguide structure 110 may be directly exposed to the cavity 118. The first support structure 106 may have a side surface 106s that is directly exposed to the cavity 118. The second support structure 108 may have a side surface 108s that is directly exposed to the cavity 118. The structure 100 described herein may be placed in ambient conditions where the waveguide structure 110 can be directly exposed to gas, vacuum, or liquid. In some implementations, the side surfaces 112s, the lower surface 112b, and the upper surface 112a of the suspended segment 112 of the waveguide structure 110 may be capable of being directly exposed to gas, vacuum, or liquid. In other words, the side surfaces 112s, the lower surface 112b, and the upper surface 112a of the suspended segment 112 of the waveguide structure 110 may not be in direct contact with any solid materials, such as dielectric materials, metals, or semiconductor materials.

The waveguide structure 110 may be configured to guide electromagnetic waves to traverse between the first supported segment 113 and the second supported segment 115. For example, light waves may be guided along the suspended segment 112 to traverse from the first supported segment 113 towards the second supported segment 115, or from the second supported segment 115 towards the first supported segment 113. In other words, the electromagnetic waves guided by the waveguide structure 110 may traverse between the position of the first support structure 106 and the position of the second support structure 108.

As shown in FIG. 2A and FIG. 3, the suspended segment 112 of the waveguide structure 110 may have a longitudinal length L. The term “longitudinal length”, when used in relation to the waveguide structure 110, may be defined as a length along the direction of the line of advance of the electromagnetic waves within the waveguide structure 110. The longitudinal length L of the suspended segment 112 of the waveguide structure 110 may be measured from the first supported segment 113 to the second supported segment 115. The electromagnetic waves may be guided to traverse along the longitudinal length L of the suspended segment 112 of the waveguide structure 110.

As shown in FIG. 2C and FIG. 3, the suspended segment 112 of the waveguide structure 110 may have a height H defined between a lowermost surface and an uppermost surface of the suspended segment 112 of the waveguide structure 110. In the example shown in FIG. 2C, the lower surface 112b can be taken as the lowermost surface and the upper surface 112a can be taken as the uppermost surface. The suspended segment 112 of the waveguide structure 110 may have a width W defined between two oppositely facing side surfaces (e.g., side surfaces 112s illustrated in FIG. 2C) of the suspended segment 112 of the waveguide structure 110. The height H and width W of the suspended segment 112 of the waveguide structure 110 may be substantially constant along the longitudinal length L of the suspended segment 112 of the waveguide structure 100. The suspended segment 112 of the waveguide structure 110 may have a cross-sectional area, which can be calculated by the multiplication of the width W and the height H of the suspended segment 112 of the waveguide structure 110. The cross-sectional area of the suspended segment 112 may be substantially constant along the longitudinal length L of the suspended segment 112.

Referring to FIG. 3A (like reference numerals in FIG. 3A refer to like features in FIG. 3), a structure 100 in a semiconductor device for use in optoelectronic or photonic applications is shown. The structure shown in FIG. 3A is an example of a modification to the structure shown in FIG. 3, where more than one waveguide structures (e.g., waveguide structures 110, 210) may be formed over a single substrate. As illustrated in FIG. 3A, waveguide structures 110, 210 and support structures 106, 108, 206, 208 may be formed over the substrate 102. Each of the waveguide structures 110, 210 may include a first supported segment (113, 213, respectively), a second supported segment (115, 215, respectively), and a suspended segment (112, 212, respectively). The supported segment 113 of the waveguide structure 110 may be directly on the support structure 106 and the supported segment 115 of the waveguide structure 110 may be directly on the support structure 108. Likewise, the supported segment 213 of the waveguide structure 210 may be directly on the support structure 206 and the supported segment 215 of the waveguide structure 210 may be directly on the support structure 208. The suspended segment 112, 212 may be between and adjoining the respective supported segment 113, 213 and the respective supported segment 115, 215. The suspended segment 112, 212 may be suspended over the substrate 102. The suspended segment 112 of waveguide structure 110 may have a height H1, a width W1, and a longitudinal length L1. The suspended segment 212 of waveguide structure 210 may have a height H2, a width W2, and a longitudinal length L2. The respective height H1, H2 and width W1, W2 of the suspended segment 112, 212 may be substantially constant along the respective longitudinal length L1, L2 of the suspended segment 112, 212.

In certain embodiments where there are more than one waveguide structures formed over the substrate, the support structures positioned below a particular waveguide structure may not extend, in a lateral direction, under and across to join the support structures positioned below an adjacent waveguide structure. For example, the support structures 106, 108 below the waveguide structure 110 may not extend, in a lateral direction, under and across to join the support structures 206, 208 below the waveguide structure 210.

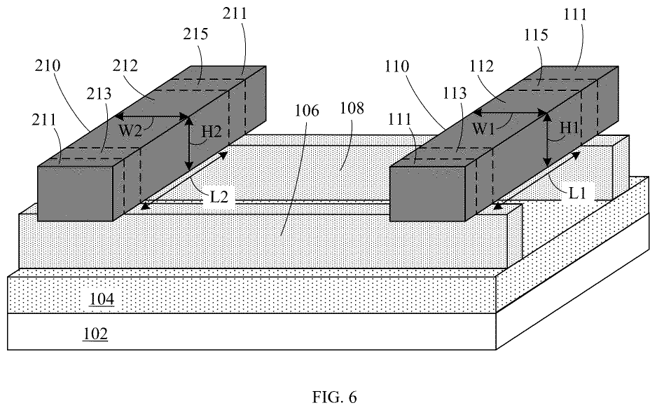

Referring to FIG. 4, FIG. 5A to FIG. 5E, and FIG. 6, another structure 100 in a semiconductor device for use in optoelectronic or photonic applications may include a first structure section 110, a second structure section 210, a first support structure 106, and a second support structure 108. In some implementations, as will be described in FIG. 17 and FIG. 18, the first structure section 110 and the second structure section 210 may be joined together to form parts of a waveguide structure. In other implementations, the first structure section 110 and the second structure section 210 may be individual discrete waveguide structures similar to the waveguide structure described in FIG. 1, FIG. 2A to FIG. 2C, and FIG. 3.

The first support structure 106 and the second support structure 108 may be over a substrate 102. The structure sections 110, 210 may each include a first supported segment 113, 213, a second supported segment 115, 215, and a suspended segment 112, 212, respectively. The first supported segment 113, 213 of the respective structure sections 110, 210 may be directly on the first support structure 106. The second supported segment 115, 215 of the respective structure sections 110, 210 may be directly on the second support structure 108. The first support structure 106 and the second support structure 108 may be elongated to extend, in a lateral direction, under and across the structure sections 110, 210. The suspended segment 112, 212 of the respective structure sections 110, 210 may be between and adjoining the first supported segment 113, 213, respectively and the second supported segment 115, 215, respectively. The suspended segment 112, 212 may be suspended over the substrate 102. A cavity 118 may be above the substrate 102, below the structure sections 110, 210, and laterally between the first support structure 106 and the second support structure 108. The cavity 118 may be either filled with gas or liquid, or in a state of vacuum.

In various implementations, an insulator layer 104 may be positioned directly on the substrate 102. The support structures 106, 108 may be positioned directly on the insulator layer 104. The cavity 118 may be above the insulator layer 104, and the insulator layer 104 may be directly exposed to the cavity 118. The suspended segment 112, 212 may be suspended over the portion of the insulator layer 104 laterally between the support structures 106, 108. In alternative implementations (not shown), the support structures 106, 108 may be positioned directly on the substrate 102, and the substrate 102 may be directly exposed to the cavity 118.

In an embodiment, the structure sections 110, 210 illustrated in FIG. 4, FIG. 5A, FIG. 5B, and FIG. 6 may have respective overhang segments 111, 211 extending from the supported segments 113, 213, and supported segments 115, 215 to suspend above the substrate 102. Alternatively, as will be shown in other drawings of the present disclosure, instead of having overhang segments 111, 211, the supported segments 113, 213 and supported segments 115, 215 may adjoin suspended segments of other structure sections.

As shown in FIG. 5A, FIG. 5B, and FIG. 5D, the supported segments 113, 115 in the structure section 110 may have respective lower surfaces 113b, 115b, while the supported segments 213, 215 in the structure section 210 may have respective lower surfaces 213b, 215b. In various implementations, the respective lower surface 113b, 115b, 213b, 215b of the supported segments 113, 115, 213, 215 may be the lowermost surface. The lower surface 113b of the supported segment 113 of the structure section 110 and the lower surface 213b of the supported segment 213 of structure section 210 may be directly on the support structure 106. The lower surface 115b of the supported segment 115 of the structure section 110 and the lower surface 215b of the supported segment 215 of structure section 210 may be directly on the support structure 108. As shown, the support structure 106 may be elongated to extend under and across the supported segment 113 of the structure section 110 and the supported segment 213 of structure section 210. The second support structure 108 may be elongated to extend under and across the supported segment 115 of the structure section 110 and the supported segment 215 of structure section 210.

As shown in FIG. 5A, FIG. 5B, and FIG. 5C, the suspended segment 112 of the first structure section 110 may have a lower surface 112b, an upper surface 112a, and side surfaces 112s. The suspended segment 212 of the second structure section 210 may have a lower surface 212b, an upper surface 212a, and side surfaces 212s. The cavity 118 may be aligned vertically below the suspended segment 112 of the first structure section 110 and the suspended segment 212 of the second structure section 210. The lower surface 112b of the suspended segment 112 of the first structure section 110 and the lower surface 212b of the suspended segment 212 of the second structure section 210 may be directly exposed to the cavity 118.

The first support structure 106 may have a side surface 106s that is directly exposed to the cavity 118. The second support structure 108 may have a side surface 108s that is directly exposed to the cavity 118. The structure 100 described herein may be placed in ambient conditions where the structure sections 110, 210 are directly exposed to gas, vacuum, or liquid. In some implementations, the side surfaces 112s, the lower surface 112b, and the upper surface 112a of the suspended segment 112 of the first structure section 110 as well as the side surfaces 212s, the lower surface 212b, and the upper surface 212a of the suspended segment 212 of the second structure section 210 may be capable of being directly exposed to gas, vacuum, or liquid. In other words, the side surfaces 112s, the lower surface 112b, and the upper surface 112a of the suspended segment 112 of the first structure section 110 as well as the side surfaces 212s, the lower surface 212b, and the upper surface 212a of the suspended segment 212 of the second structure section 210 may not be in direct contact with any solid materials, such as dielectric materials, metals, or semiconductor materials.

Each of the structure sections 110, 210 may be configured to guide electromagnetic waves to traverse between the respective first supported segment 113, 213 and the second supported segment 115, 215. For example, in the first structure section 110, light waves may be guided along the suspended segment 112 to traverse from the first supported segment 113 towards the second supported segment 115, or from the second supported segment 115 towards the first supported segment 113. Likewise, in the second structure section 210, light waves may be guided along the suspended segment 212 to traverse from the first supported segment 213 towards the second supported segment 215, or from the second supported segment 215 towards the first supported segment 213. In other words, the electromagnetic waves guided by the structure sections 110, 210 may traverse between the position of the first support structure 106 and the position of the second support structure 108.

As shown in FIG. 5A, FIG. 5B, and FIG. 6, the suspended segment 112, 212 of the respective structure sections 110, 210 may have a longitudinal length L1, L2, respectively. The term “longitudinal length”, when used in relation to the structure sections 110, 210, may be defined as a length along the direction of the line of advance of the electromagnetic waves within the structure sections 110, 210. The respective longitudinal length L1, L2 of the suspended segment 112, 212 may be measured from the respective first supported segment 113, 213 to the second supported segment 115, 215. The electromagnetic waves may be guided to traverse along the longitudinal length L1 of the suspended segment 112 of the structure section 110, and along the longitudinal length L2 of the suspended segment 212 of the structure section 210.

As shown in FIG. 5C and FIG. 6, the suspended segment 112 of the first structure section 110 may have a height H1 defined between a lowermost surface and an uppermost surface of the suspended segment 112 of the first structure section 110. The suspended segment 212 of the second structure section 210 may have a height H2 defined between a lowermost surface and an uppermost surface of the suspended segment 212 of the second structure section 210. In the example shown in FIG. 5C, the lower surface 112b can be taken as the lowermost surface of the suspended segment 112 and the upper surface 112a can be taken as the uppermost surface of the suspended segment 112. The lower surface 212b can be taken as the lowermost surface of the suspended segment 212 and the upper surface 212a can be taken as the uppermost surface of the suspended segment 212.

The suspended segment 112 of the first structure section 110 may have a width W1 defined between two oppositely facing side surfaces (e.g., side surfaces 112s illustrated in FIG. 5C) of the suspended segment 112 of the first structure section 110. The height H1 and width W1 of the suspended segment 112 of the first structure section 110 may be substantially constant along the longitudinal length L1 of the suspended segment 112 of the first structure section 110. The suspended segment 112 of the first structure section 110 may have a cross-sectional area, which can be calculated by the multiplication of the width W1 and the height H1 of the suspended segment 112 of the first structure section 110. The cross-sectional area of the suspended segment 112 may be substantially constant along the longitudinal length L1 of the suspended segment 112.

The suspended segment 212 of the second structure section 210 may have a width W2 defined between two oppositely facing side surfaces (e.g., side surfaces 212s illustrated in FIG. 5C) of the suspended segment 212 of the second structure section 210. The height H2 and width W2 of the suspended segment 212 of the second structure section 210 may be substantially constant along the longitudinal length L2 of the suspended segment 212 of the second structure section 210. The suspended segment 212 of the second structure section 210 may have a cross-sectional area, which can be calculated by the multiplication of the width W2 and the height H2 of the suspended segment 212 of the second structure section 210. The cross-sectional area of the suspended segment 212 may be substantially constant along the longitudinal length L2 of the suspended segment 212.

Although the structures illustrated in FIG. 5C and FIG. 6 may depict that the height H1 and width W1 of the suspended segment 112 are substantially the same as the height H2 and the width W2 of the suspended segment 212, respectively, it should be understood that in certain implementations, the height H1 and width W1 of the suspended segment 112 may be different from the height H2 and the width W2 of the suspended segment 212.

The substrate 102 may be made of any semiconductor material, such as silicon, germanium, silicon germanium (SiGe), silicon carbide, and those consisting essentially of III-V compound semiconductors, such as GaAs, II-VI compound semiconductors such as ZnSe. The substrate 102 may have an amorphous, polycrystalline, or monocrystalline structure. The insulator layer 104 may include an oxide (e.g., silicon dioxide, germanium dioxide, etc.) or a nitride (e.g., silicon nitride, germanium nitride, etc.).

The waveguide structure 110 described in FIG. 1, FIG. 2A to FIG. 2C, and FIG. 3 and the structure sections 110, 210 described in FIG. 4, FIG. 5A to FIG. 5E, and FIG. 6 may be made of either a semiconductor material or a dielectric material. Examples of the semiconductor material for the waveguide structure and structure sections may include, but are not limited to, amorphous silicon, polycrystalline silicon, amorphous germanium, polycrystalline germanium, amorphous SiGe, or polycrystalline SiGe. Examples of the dielectric material for the waveguide structure and structure sections may include, but are not limited to, silicon dioxide, silicon nitride (SiN), silicon oxynitride (SiON), aluminum nitride (AlN), or other nitride-containing compounds. Preferably, the waveguide structure and structure sections described herein may include a semiconductor material, such as silicon or germanium. The support structures 106, 108 may be of the same material as the insulator layer 104 and may be of a different material from the waveguide structure 110 described in FIG. 1, FIG. 2A to FIG. 2C, and FIG. 3 and the structure sections 110, 210 described in FIG. 4, FIG. 5A to FIG. 5E, and FIG. 6.

By designing the waveguide structure 110 described in FIG. 1, FIG. 2A to FIG. 2C, and FIG. 3 and the structure sections 110, 210 described in FIG. 4, FIG. 5A to FIG. 5E, and FIG. 6 to have supported segments 113, 115 that directly contact the support structures 106, 108 and suspended segments 112, 212 to have lower surfaces that are directly exposed to the underlying cavity 118, it is found that the area of direct contact between the waveguide structure 110, or the structure sections 110, 210, and the support structures 106, 108 can be reduced, thus minimizing optical signal loss to the support structures 106, 108 (or inadvertent absorption of optical signals by the support structures 106, 108), and improving the detection sensitivity of any optoelectronic component connected to the waveguide structure 110 or structure sections 110, 210.

The present disclosure may provide a method of forming a structure in a semiconductor device for use in optoelectronic or photonic applications, a method of forming a semiconductor device for use in optoelectronic or photonic applications, and a method of forming an IC chip for use in optoelectronic or photonic applications. The method may include forming a first support structure over a substrate, forming a second support structure over the substrate, forming a waveguide structure over the first support structure and the second support structure, and forming a cavity above the substrate and laterally between the first support structure and the second support structure. Forming the waveguide structure may include forming a first supported segment of the waveguide structure directly on the first support structure, forming a second supported segment of the waveguide structure directly on the second support structure, and forming a suspended segment of the waveguide structure between and adjoining the first supported segment and the second supported segment. The suspended segment may be formed to suspend over the substrate, and the suspended segment of the waveguide structure may be formed with a lower surface directly exposed to the cavity. The method may also include forming an optoelectronic component over the substrate, in which the waveguide structure may be connected to the optoelectronic component.

The present disclosure may also provide another method of forming a structure in a semiconductor device for use in optoelectronic or photonic applications, another method of forming a semiconductor device for use in optoelectronic or photonic applications, and another method of forming an IC chip for use in optoelectronic or photonic applications. The method may include forming a first support structure over a substrate, forming a second support structure over the substrate, forming a waveguide structure having a plurality of structure sections, each structure section is formed over the first support structure and the second support structure, and forming a cavity above the substrate and laterally between the first support structure and the second support structure. Forming each structure section may include forming a first supported segment of each structure section directly on the first support structure, forming a second supported segment of each structure section directly on the second support structure, and forming a suspended segment of each structure section between and adjoining the first supported segment and the second supported segment. The suspended segment may be formed to suspend over the substrate, and the suspended segment of each structure section may be formed with a lower surface directly exposed to the cavity.

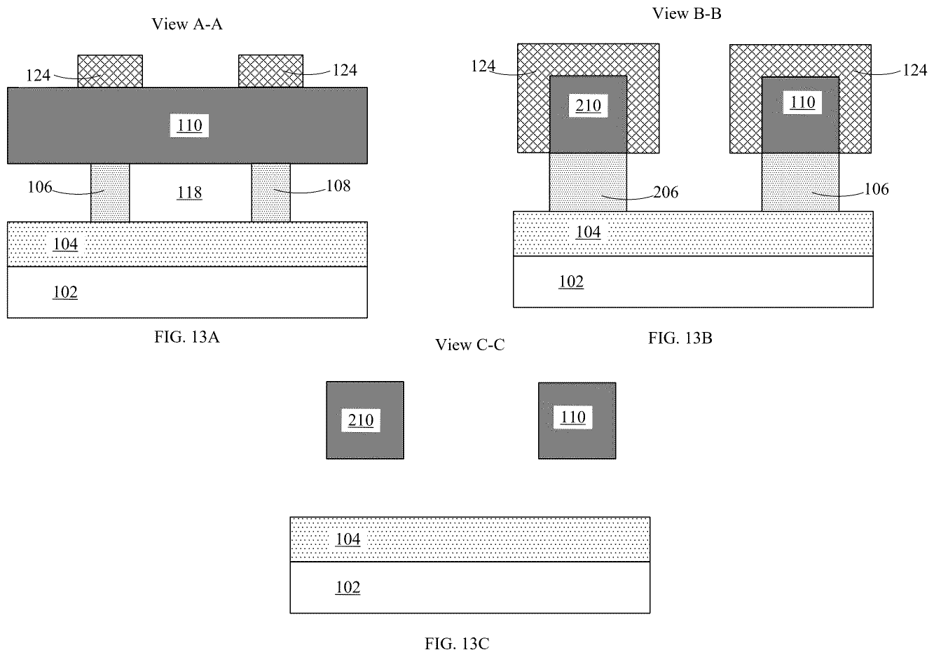

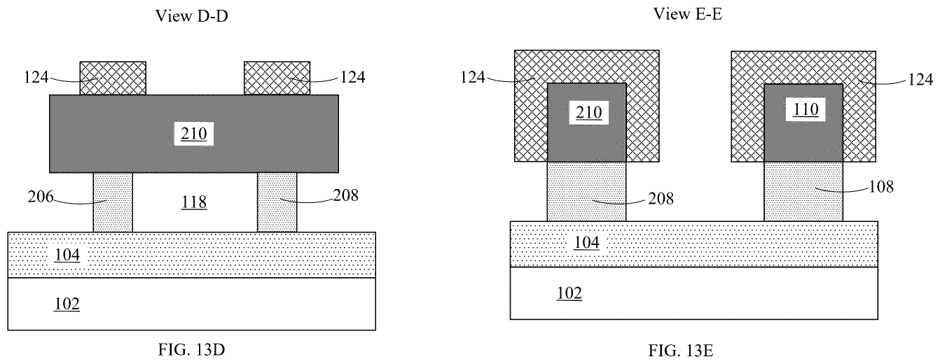

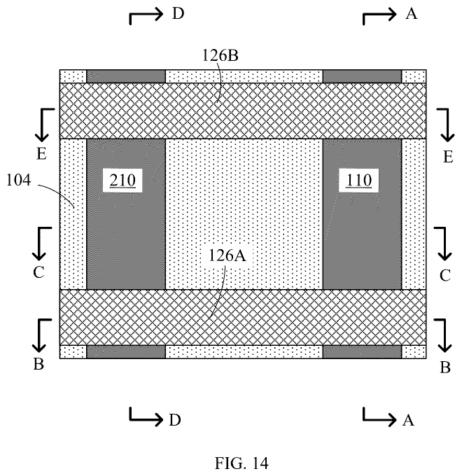

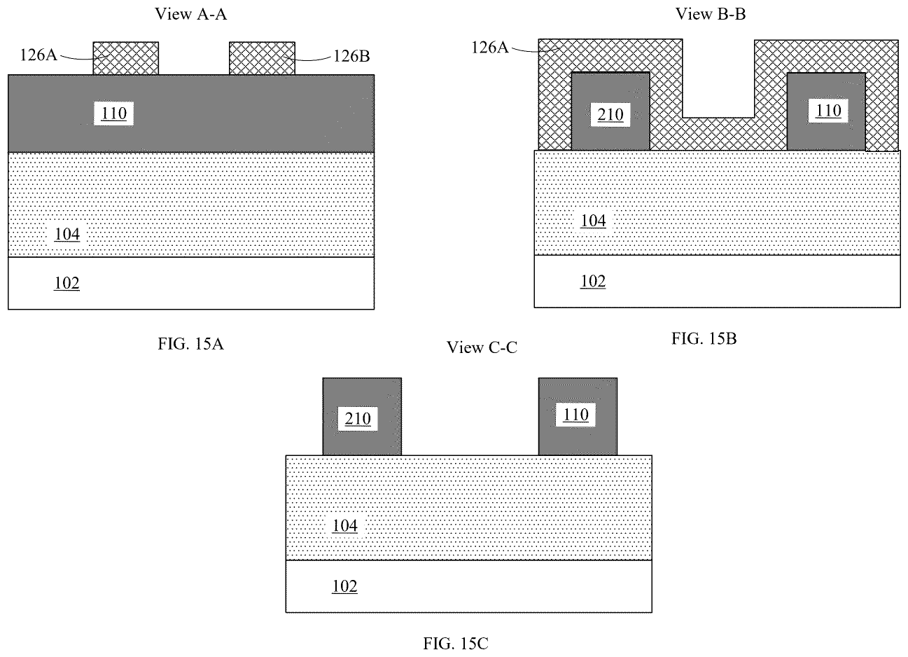

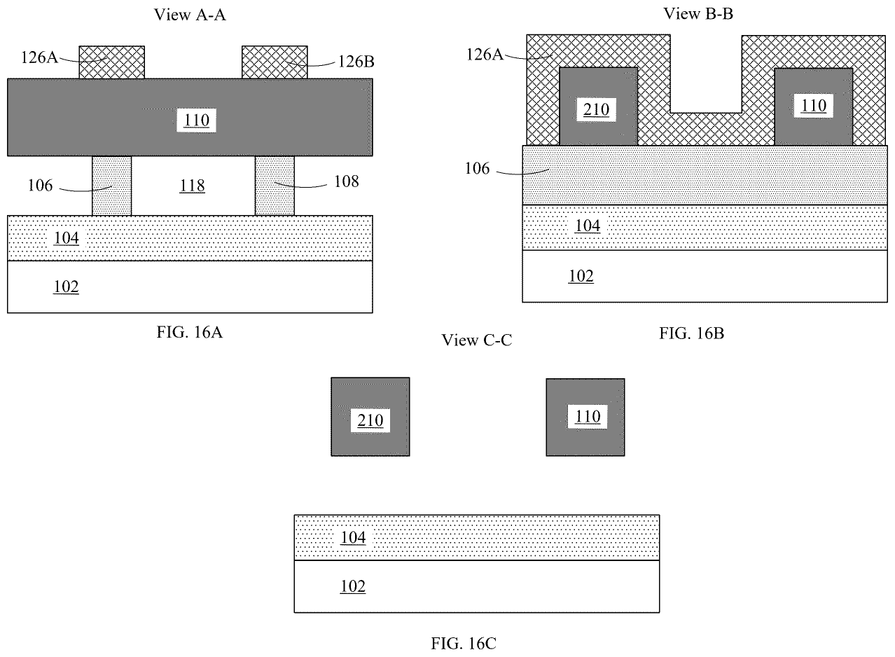

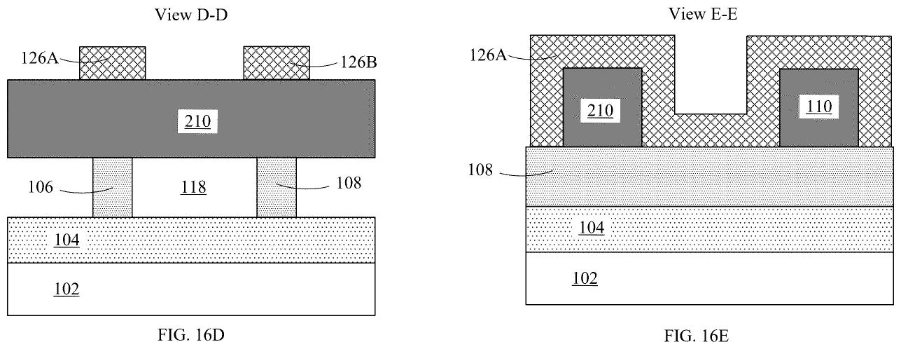

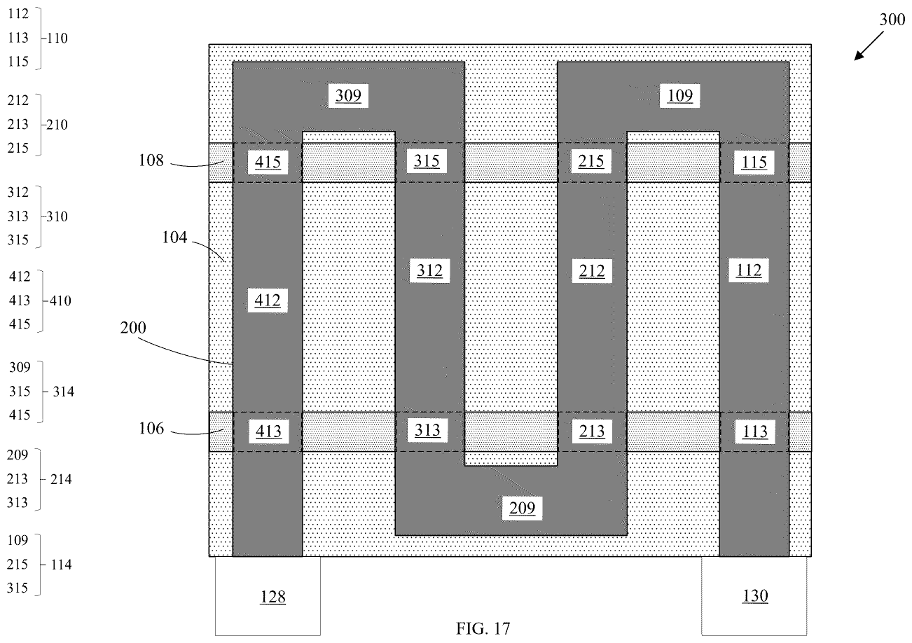

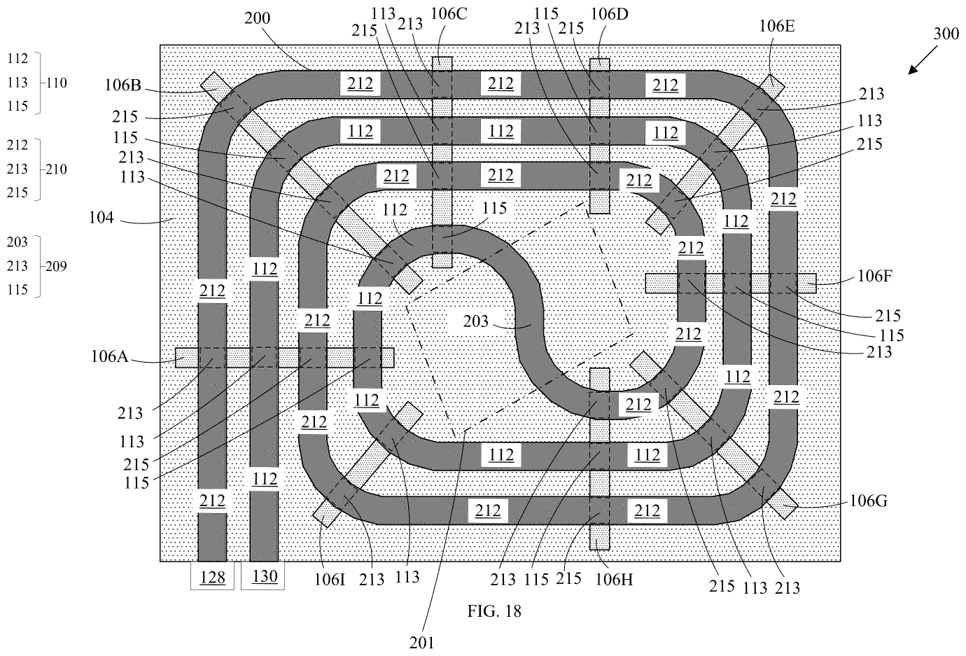

FIG. 7, FIG. 8A and FIG. 8B, FIG. 9, FIG. 10A and FIG. 10B, FIG. 11, FIG. 12A to FIG. 12C, and FIG. 13A to FIG. 13C show a set of steps that may be used to form the example structure shown in FIG. 1, FIG. 2A to FIG. 2C, and FIG. 3.

As used herein, “deposition techniques” refer to the process of applying a material over another material (or the substrate). Exemplary techniques for deposition include, but are not limited to, spin-on coating, sputtering, chemical vapor deposition (CVD), physical vapor deposition (PVD), electrochemical deposition (ECD), molecular beam deposition (MBD), pulsed laser deposition (PLD), liquid source misted chemical deposition (LSMCD), atomic layer deposition (ALD).

Additionally, “patterning techniques” include deposition of material or photoresist, patterning, exposure, development, etching, cleaning, and/or removal of the material or photoresist as required in forming a described pattern, structure, or opening. Examples of techniques for patterning include, but are not limited to, wet etch lithographic processes, dry etch lithographic processes, or direct patterning processes. Such techniques may use mask sets and resist layers.

Referring to FIG. 7, FIG. 8A, and FIG. 8B, a device structure for forming the example structure in the semiconductor device as disclosed herein is shown. FIG. 7 is a top-down view of the device structure. FIG. 8A is a cross-sectional view taken along section line AA in FIG. 7 and FIG. 8B is a cross-sectional view taken along section line BB in FIG. 7. As shown, a material layer 120 may be formed above the substrate 102. In some implementations, an insulator layer 104 may be formed directly on the substrate 102, and the material layer 120 may be formed directly on the insulator layer 104. In other implementations (not shown), the material layer 120 may be formed directly on the substrate 102. As an illustrative example, the material layer 120 may be a semiconductor material layer 120, although the present disclosure also contemplates other material types, such as a dielectric material layer. The semiconductor material layer 120 may be subsequently patterned, using the patterning techniques described herein. For example, a first set of patterned mask layers 122 may be formed on the semiconductor material layer 120 using deposition techniques. The patterned mask layers 122 may cover sections of the semiconductor material layer 120, while exposed sections of the semiconductor material layer 120 may be subsequently etched. The semiconductor material layer 120 may include amorphous silicon, polycrystalline silicon, amorphous germanium, polycrystalline germanium, amorphous SiGe, or polycrystalline SiGe.

FIG. 9 is a top-down view of the device structure at a stage of fabrication subsequent to FIG. 7. FIG. 10A is a cross-sectional view taken along section line AA in FIG. 9 and FIG. 10B is a cross-sectional view taken along section line BB in FIG. 9. Referring to FIG. 9 (FIG. 9 continues from the illustration shown in FIG. 7), FIG. 10A (FIG. 10A continues from the illustration shown in FIG. 8A), and FIG. 10B (FIG. 10B continues from the illustration shown in FIG. 8B), the semiconductor material layer 120 may be etched using the patterning techniques to form waveguide structures 110, 210. The etching of the semiconductor material layer 120 may also expose portions of the insulator layer 104 that are not covered by the waveguide structures 110, 210. The patterned mask layers 122 may be removed after the formation of the waveguide structures 110, 210.

FIG. 11 is a top-down view of the device structure at a stage of fabrication subsequent to FIG. 9. FIG. 12A is a cross-sectional view taken along section line AA in FIG. 11, FIG. 12B is a cross-sectional view taken along section line BB in FIG. 11, and FIG. 12C is a cross-sectional view taken along section line CC in FIG. 11. Referring to FIG. 11 (FIG. 11 continues from the illustration shown in FIG. 9), FIG. 12A (FIG. 12A continues from the illustration shown in FIG. 10A), FIG. 12B (FIG. 12B continues from the illustration shown in FIG. 10B), and FIG. 12C, patterned mask layers 124 may be formed on the waveguide structures 110, 210 using deposition techniques. As shown in FIG. 11, two patterned mask layers 124 may be formed on each of the waveguide structures 110, 210. In the illustrative example shown in FIG. 12A, the two patterned mask layers 124 formed on the waveguide structure 110 may be spaced apart from each other. As shown in FIG. 12B, at positions on the waveguide structures 110, 210 where the patterned mask layers 124 are formed, the patterned mask layers 124 may cover the side surfaces and the upper surface of the respective waveguide structures 110, 210. Additionally, the patterned mask layer 124 formed on the side surfaces of the respective waveguide structures 110, 210 may also partially cover portions of the insulator layer 104 laterally and proximally adjacent to the waveguide structures 110, 210. FIG. 12C illustrates cross-sectional views of the waveguide structures 110, 210 at positions where the patterned mask layers 124 are not formed on the side surfaces and the upper surface of the respective waveguide structures 110, 210.

FIG. 13A is a cross-sectional view taken along section line AA in FIG. 11, FIG. 13B is a cross-sectional view taken along section line BB in FIG. 11, FIG. 13C is a cross-sectional view taken along section line CC in FIG. 11, FIG. 13D is a cross-sectional view taken along section line DD in FIG. 11, and FIG. 13E is a cross-sectional view taken along section line EE in FIG. 11. Referring to FIG. 13A (FIG. 13A continues from the illustration shown in FIG. 12A), FIG. 13B (FIG. 13B continues from the illustration shown in FIG. 12B), FIG. 13C (FIG. 13C continues from the illustration shown in FIG. 12C), FIG. 13D, and FIG. 13E, the insulator layer 104 may be etched using the patterning techniques to form support structures 106, 108, 206, 208 on the insulator layer 104. Each support structure 106, 206, 108, 208 may be aligned vertically below the positions of each patterned mask layer 124. As shown in FIG. 13B and FIG. 13E, the support structures 106, 108 formed below the waveguide structure 110 are spaced apart from the support structures 206, 208 formed below the waveguide structure 210. In other words, the support structures 106, 108 formed below the waveguide structure 110 may not be joined to the support structures 206, 208 formed below the waveguide structure 210. As shown in FIG. 13A and FIG. 13D, the etching of the insulator layer 104 may also form a cavity 118 below the waveguide structure 110 and laterally between the support structures 106, 108, and below the waveguide structure 210 and laterally between the support structures 206, 208. With the formation of the cavity 118, segments of the waveguide structures 110, 210 may be suspended over the remaining insulator layer 104 while other segments of the waveguide structures 110, 210 may be supported directly on the support structures 106, 108.

The support structures 106, 108, 206, 208 and the cavity 118 may be formed by an etching process in which the etching of the insulator layer 104 occurs in all directions (e.g., lateral and vertical directions). The etching process may utilize a wet etchant or a dry etchant, and may employ one or more etching steps. During the etching of the insulator layer 104, at positions on the side surfaces and the upper surface of the respective waveguide structures 110, 210 where the patterned mask layers 124 are absent (as shown in FIG. 13C), portions of the insulator layer 104 aligned vertically below the waveguide structures 110, 210 may be fully removed, for example, by having the etchant etch the material of the insulator layer 104 along the lateral direction, thereby forming the cavity 118. However, at positions on the side surfaces and the upper surface of the respective waveguide structures 110, 210 where the patterned mask layers 124 are present (as shown in FIG. 13A, FIG. 13B, FIG. 13D, and FIG. 13E), portions of the insulator layer 104 may not be fully removed along the lateral direction. The presence of the patterned mask layers 124 on the waveguide structures 110, 210 may increase the lateral etch distance of the portions of the insulator layer 104 covered by the patterned mask layers 124. Accordingly, the portions of the insulator layer 104 covered by the patterned mask layers 124 may only be partially etched along the lateral direction, and the remaining un-etched portions of the insulator layer 104 may form the support structures 106, 108, 206, 208. The patterned mask layers 124 may be removed thereafter.

FIG. 14 is a top-down view of the device structure at a stage of fabrication subsequent to FIG. 9. FIG. 15A is a cross-sectional view taken along section line AA in FIG. 14, FIG. 15B is a cross-sectional view taken along section line BB in FIG. 14, and FIG. 15C is a cross-sectional view taken along section line CC in FIG. 14. Referring to FIG. 14 (FIG. 14 continues from the illustration shown in FIG. 9), FIG. 15A (FIG. 15A continues from the illustration shown in FIG. 10A), FIG. 15B (FIG. 15B continues from the illustration shown in FIG. 10B), and FIG. 15C, an alternative set of patterned mask layers 126A, 126B may be formed on the waveguide structures 110, 210 using deposition techniques. The patterned mask layers 126A, 126B shown in FIG. 14 differ from the patterned mask layers 124 shown in FIG. 11 in that each patterned mask layer 126A, 126B shown in FIG. 14 may straddle across both waveguide structures 110, 210 shown in FIG. 14. Since each patterned mask layer 126A, 126B straddles across both waveguide structures 110, 210, the respective patterned mask layer 126A, 126B may also cover a strip of the insulator layer 104 laterally between the waveguide structures 110, 210. As shown in FIG. 14 and FIG. 15B, each of the patterned mask layers 126A, 126B may be formed on the side surfaces and the upper surface of the respective waveguide structures 110, 210 and portions of the insulator layer 104 laterally adjacent to the waveguide structures 110, 210. In the example shown in FIG. 15A, the patterned mask layer 126A may be spaced apart from the patterned mask layer 126B. FIG. 15C illustrates cross-sectional views of the waveguide structures 110, 210 at positions where the patterned mask layers 126A, 126B are not formed on the side surfaces and the upper surface of the respective waveguide structures 110, 210.

FIG. 16A is a cross-sectional view taken along section line AA in FIG. 14, FIG. 16B is a cross-sectional view taken along section line BB in FIG. 14, FIG. 16C is a cross-sectional view taken along section line CC in FIG. 14, FIG. 16D is a cross-sectional view taken along section line DD in FIG. 14, and FIG. 16E is a cross-sectional view taken along section line EE in FIG. 14. Referring to FIG. 16A (FIG. 16A continues from the illustration shown in FIG. 15A), FIG. 16B (FIG. 16B continues from the illustration shown in FIG. 15B), FIG. 16C (FIG. 16C continues from the illustration shown in FIG. 15C), FIG. 16D, and FIG. 16E, the insulator layer 104 may be etched using the patterning techniques to form support structures 106, 108 on the insulator layer 104. Each support structure 106, 108 may be aligned vertically below the positions of each patterned mask layer 126A, 126B. As shown in FIG. 16A and FIG. 16D, the etching of the insulator layer 104 may also form a cavity 118 below the waveguide structures 110, 210 and laterally between the support structures 106, 108. With the formation of the cavity 118, segments of the waveguide structures 110, 210 may be suspended over the remaining insulator layer 104 while other segments of the waveguide structures 110, 210 may be supported directly on the support structures 106, 108.

The formation of the support structures 106, 108 and the cavity 118 may be formed by an etching process where the etching of the insulator layer 104 occurs in all directions (e.g., lateral and vertical directions). The etching process may utilize a wet etchant or a dry etchant, and may employ one or more etching steps. During the etching of the insulator layer 104, at positions on the side surfaces and the upper surface of the respective waveguide structures 110, 210 where the patterned mask layers 126A, 126B are absent (as shown in FIG. 15C), portions of the insulator layer 104 aligned vertically below the waveguide structures 110, 210 may be fully removed, for example, by having the etchant etch the material of the insulator layer 104 along the lateral direction, thereby forming the cavity 118. However, at positions on the side surfaces and the upper surface of the respective waveguide structures 110, 210 and on strips of the insulator layer 104 laterally between the waveguide structures 110, 210 where the patterned mask layers 126A, 126B are present (as shown in FIG. 15A, FIG. 15B, FIG. 15D, and FIG. 15E), portions of the insulator layer 104 may not be fully removed along the lateral direction. The presence of the patterned mask layers 126A, 126B may increase the lateral etch distance of the portions of the insulator layer 104 covered by the patterned mask layers 126A, 126B. Accordingly, the portions of the insulator layer 104 covered by the patterned mask layers 126A, 126B may only be partially etched along the lateral direction, and the remaining un-etched portions of the insulator layer 104 may form the support structures 106, 108. The patterned mask layers 126A, 126B may be removed thereafter.

The present disclosure may also provide an IC chip including an optoelectronic component, a first support structure over a substrate, a second support structure over the substrate, a waveguide structure connected to the optoelectronic component, the waveguide structure having a first supported segment directly on the first support structure, a second supported segment directly on the second support structure, and a suspended segment between and adjoining the first supported segment and the second supported segment, and a cavity above the substrate and laterally between the first support structure and the second support structure, in which the suspended segment is suspended over the substrate, and the suspended segment of the waveguide structure has a lower surface directly exposed to the cavity. The waveguide structure may be configured to guide electromagnetic waves to traverse between the first supported segment and the second supported segment.

FIG. 17 and FIG. 18 illustrate examples of IC chips, for use in optoelectronic or photonic applications, incorporating the exemplary structure in a semiconductor device as described in FIG. 1, FIG. 2A to FIG. 2C, FIG. 3, FIG. 4, FIG. 5A to FIG. 5E, and FIG. 6. Referring to FIG. 17, an example of the IC chip 300 may include optoelectronic components 128, 130, a first support structure 106, a second support structure 108, and a waveguide structure 200 connected to the optoelectronic components 128, 130. The waveguide structure 200 may include a plurality of structure sections 110, 210, 310, 410, 114, 214, 314. Each structure section 110, 210, 310, 410, 114, 214, 314 may include a first supported segment 113, 213, 313, 413 directly on the first support structure 106, a second supported segment 115, 215, 315, 415 directly on the second support structure 108, and a suspended segment 112, 212, 312, 412, 109, 209, 309 between and adjoining the respective first supported segment 113, 213, 313, 413 and the second supported segment 115, 215, 315, 415. The structure sections 110, 210, 310, 410, 114, 214, 314 in the waveguide structure 200 may be joined to form a serpentine pattern. For example, the plurality of structure sections 110, 210, 310, 410, 114, 214, 314 may include straight structure sections 110, 210, 310, 410 and turning structure sections 114, 214, 314 arranged in series. The plurality of structure sections 110, 210, 310, 410, 114, 214, 314 may alternate between the straight structure sections 110, 210, 310, 410 and the turning structure sections 114, 214, 314 in the series arrangement. Each of the straight structure sections 110, 210, 310, 410 may have a suspended segment 112, 212, 312, 412 having a straight elongated body without turns, whereas each of the turning structure sections 114, 214, 314 may have a suspended segment 109, 209, 309 having turns or bends. The straight structure sections 110, 210, 310, 410 may extend perpendicularly across the first support structure 106 and the second support structure 108. The support structures 106, 108 may be elongated to extend under and across the straight structure sections 110, 210, 310, 410.

Referring to FIG. 18, another example of the IC chip 300 may include optoelectronic components 128, 130, a plurality of support structures 106A, 106B, 106C, 106D, 106E, 106F, 106G, 106H, 106I and a waveguide structure 200 connected to the optoelectronic components 128, 130. The waveguide structure 200 may include a plurality of structure sections 110, 210, 209. The structure sections 110, 210, 209 may be joined to form a double spiral pattern. The double spiral pattern may have a center region 201. The center region 201 may include a structure section 209 with an inflection point 203. As used herein, the term “double spiral pattern” may refer to a Fermat's spiral or a spiral pattern having turns that spiral inward to the center region 201 and turns that spiral outward from the center region 201. The inflection point 203 may refer to the point in the double spiral pattern where the turns of the double spiral pattern change from the inward spiral to the outward spiral. The plurality of support structures 106A, 106B, 106C, 106D, 106E, 106F, 106G, 106H, 106I may extend radially, along a lateral direction, towards the center region 201 of the double spiral pattern. The support structures 106A, 106B, 106C, 106D, 106E, 106F, 106G, 106H, 106I may be elongated to extend under and across the structure sections 110, 210. Each structure section 110, 210 may include a first supported segment 113, 213, a second support segment 115, 215, and a suspended segment 112, 212 between and adjoining the respective first supported segment 113, 213 and the second supported segment 115, 215. The first supported segment 113, 213 and the second supported segment 115, 215 may be directly on the respective support structures 106A, 106B, 106C, 106D, 106E, 106F, 106G, 106H, 106I. The structure section 209 in the center region 201 may include supported segments 115, 213, in which the inflection point 203 is laterally between the supported segment 115 and the supported segment 213.

The optoelectronic components 128, 130 may be optically connected to the waveguide structures 200 described in FIG. 17 and FIG. 18 such that electromagnetic waves, such as light, can enter and exit the waveguide structures 200. Examples of the optoelectronic components 128, 130 may include, but are not limited to, photodetectors, waveguide couplers, optical fibers, lasers, optical modulators, and interferometers. The optoelectronic components 128, 130 may be formed over the same substrate as the waveguide structures 200. The IC chip 300 may be a monolithic IC chip where the waveguide structures 200, the optoelectronic components 128, 130, and other chip components may be fabricated on a single substrate or a single semiconductor base material, as opposed to being fabricated on different substrates that are assembled or packaged together.

The structure 100 described in FIG. 1, FIG. 2A to FIG. 2C, FIG. 3, FIG. 4, FIG. 5A to FIG. 5E, and FIG. 6, and the IC chip 300 described in FIG. 17 to FIG. 18 may be configured for use as a sensor, in which the sensor may be capable of sensing a medium. For example, the side surfaces 112s, the lower surface 112b, and the upper surface 112a of the suspended segment 112 of the waveguide structure 110 described in FIG. 1, FIG. 2A to FIG. 2C, and FIG. 3 and the side surfaces 112s, the lower surface 112b, and the upper surface 112a of the suspended segment 112 of the first structure section 110 as well as the side surfaces 212s, the lower surface 212b, and the upper surface 212a of the suspended segment 212 of the second structure section 210 may be exposed to a medium to be sensed by the sensor. The medium to be sensed by the sensor may flow through the cavity 118 described herein. The medium to be sensed by the sensor may be a fluid and may include matter in a gaseous state, a liquid state, or both.

Throughout this disclosure, it is to be understood that if a method is described herein as involving a series of steps, the order of such steps as presented herein is not necessarily the only order in which such steps may be performed, and certain of the stated steps may possibly be omitted and/or certain other steps not described herein may possibly be added to the method. Furthermore, the terms “comprise”, “include”, “have”, and any variations thereof, are intended to cover a non-exclusive inclusion, such that a process, method, article, or device that comprises a list of elements is not necessarily limited to those elements, but may include other elements not expressly listed or inherent to such process, method, article, or device. Occurrences of the phrase “in an embodiment” herein do not necessarily all refer to the same embodiment, occurrences of the phrase “in an implementation” herein do not necessarily all refer to the same implementation, and occurrences of the phrase “in an example” herein do not necessarily all refer to the same example.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein. Furthermore, there is no intention to be bound by any theory presented in the preceding background or the following detailed description. Additionally, the various tasks and processes described herein may be incorporated into a more comprehensive procedure or process having additional functionality not described in detail herein.

References herein to terms modified by language of approximation, such as “about”, “approximately”, and “substantially”, are not to be limited to the precise value specified. The language of approximation may correspond to the precision of an instrument used to measure the value and, unless otherwise dependent on the precision of the instrument, may indicate +/−10% of the stated value(s).

As will be readily apparent to those skilled in the art upon a complete reading of the present application, the semiconductor devices and methods disclosed herein may be employed in manufacturing a variety of different integrated circuit products and modules, including, but not limited to, CMOS devices, optoelectronic modules, LIDAR instrumentation, and LIDAR systems, etc.

What is claimed is:

1. A structure in a semiconductor device, the structure comprising:
a first support structure over a substrate;
a second support structure over the substrate;
a waveguide structure having a first segment directly on the first support structure, a second segment directly on the second support structure, and a suspended segment between and adjoining the first segment and the second segment, wherein the waveguide structure is configured to guide electromagnetic waves to traverse between the first segment and the second segment; and
a cavity above the substrate and laterally between the first support structure and the second support structure, wherein the suspended segment has a lower surface directly exposed to the cavity.

2. The structure of claim 1, wherein the suspended segment has side surfaces and an upper surface, and wherein the side surfaces, the lower surface, and the upper surface of the suspended segment are capable of being directly exposed to gas, vacuum, or liquid.

3. The structure of claim 2, wherein the first segment of the waveguide structure has a lower surface directly on the first support structure, and the second segment of the waveguide structure has a lower surface directly on the second support structure.

4. The structure of claim 1, wherein the suspended segment of the waveguide structure has a longitudinal length, and the electromagnetic waves are guided to traverse along the longitudinal length of the suspended segment of the waveguide structure.

5. The structure of claim 4, wherein the suspended segment of the waveguide structure has a cross-sectional area, the cross-sectional area of the suspended segment is constant along the longitudinal length of the suspended segment.

6. The structure of claim 4, wherein the suspended segment of the waveguide structure has a height and a width, the height and width of the suspended segment of the waveguide structure are constant along the longitudinal length of the suspended segment of the waveguide structure.

7. A structure in a semiconductor device, the structure comprising:
a first support structure over a substrate;
a second support structure over the substrate;
a waveguide structure having a plurality of structure sections, each structure section includes a first supported segment directly on the first support structure, a second supported segment directly on the second support structure, and a suspended segment between and adjoining the first supported segment and the second supported segment, wherein the waveguide structure is configured to guide electromagnetic waves to traverse, in each structure section, between the first supported segment and the second supported segment; and
a cavity above the substrate and laterally between the first support structure and the second support structure, wherein the suspended segment in each structure section of the plurality of structure sections is suspended over the substrate, and the suspended segment in each structure section of the plurality of structure sections has a lower surface directly exposed to the cavity.

8. The structure of claim 7, wherein the structure sections in the waveguide structure are joined to form a serpentine pattern.

9. The structure of claim 8, wherein the plurality of structure sections includes straight structure sections and turning structure sections arranged in series, the plurality of structure sections alternates between the straight structure sections and the turning structure sections in the series arrangement, and wherein the straight structure sections in the plurality of structure sections extends perpendicularly across the first support structure and the second support structure.

10. The structure of claim 7, wherein the structure sections in the waveguide structure are joined to form a double spiral pattern, the double spiral pattern having a center region.

11. The structure of claim 10, further comprising a plurality of support structures, the plurality of support structures includes the first support structure and the second support structure, and the plurality of support structures extends radially towards the center region of the double spiral pattern.

12. The structure of claim 7, wherein the first support structure and the second support structure are elongated to extend under and across each structure section in the plurality of structure sections.

13. The structure of claim 7, wherein the suspended segment in each structure section has a longitudinal length, and the electromagnetic waves are guided to traverse along the longitudinal length of the suspended segment in each structure section of the waveguide structure.

14. The structure of claim 13, wherein the suspended segment in each structure section has a cross-sectional area, the cross-sectional area of the suspended segment is constant along the longitudinal length of the suspended segment.

15. The structure of claim 13, wherein the suspended segment in each structure section has a height and a width, the height and width of the suspended segment are constant along the longitudinal length of the suspended segment.

16. A structure in a semiconductor device, the structure comprising:
a first support structure over a substrate;
a second support structure over the substrate;
a waveguide structure having a first supported segment directly on the first support structure, a second supported segment directly on the second support structure, and a suspended segment between and adjoining the first supported segment and the second supported segment, the suspended segment of the waveguide structure has a longitudinal length and a cross-sectional area, wherein the cross-sectional area of the suspended segment of the waveguide structure is constant along the longitudinal length of the suspended segment of the waveguide structure; and
a cavity above the substrate and laterally between the first support structure and the second support structure, wherein the suspended segment is suspended over the substrate, and the suspended segment of the waveguide structure has a lower surface directly exposed to the cavity.

17. The structure of claim 16, wherein the suspended segment of the waveguide structure has a height and a width, the height and width of the suspended segment of the waveguide structure are constant along the longitudinal length of the suspended segment of the waveguide structure.

18. The structure of claim 17, wherein the suspended segment has side surfaces and an upper surface, and wherein the side surfaces, the lower surface, and the upper surface of the suspended segment of the waveguide structure are capable of being directly exposed to gas, vacuum, or liquid.

19. The structure of claim 17, wherein the waveguide structure is configured to guide electromagnetic waves to traverse between the first supported segment and the second supported segment, and along the longitudinal length of the suspended segment of the waveguide structure.

20. The structure of claim 18, wherein the structure is configured as a sensor capable of sensing a medium, and the medium to be sensed by the sensor flows through the cavity.
